(19) United States
(12) Patent Application Publication
(10) Pub. No.: US 2002/0130360 A1
(43) Pub. Date: Sep. 19, 2002

(54) High voltage MOS device with no field oxide over the p-top region

(75) Inventors: Mohamed Imam, Tempe, AZ (US); Evgueniy N. Stefanov, Vieille Toulouse (FR); Zia Hossain, Tempe, AZ (US); Mohammed Tanvir Quddus, Tempe, AZ (US); Joe Fulton, Chandler, AZ (US)

Correspondence Address: Robert D. Atkins, ON Semiconductor, Patent Administration Dept - MD A230, P.O. Box 62890, Phoenix, AZ, 85082-2890, US

(73) Assignee: Semiconductor Components Industries, LLC.

(21) Appl. No.: 09/808,965

(22) Filed: Mar. 16, 2001

(51) Int. Cl. H01L 21/336; H01L 29/76; H01L 29/94; H01L 31/113; H01L 31/119

(52) U.S. Cl. 257/335; 438/282

(57) ABSTRACT

A high voltage MOS device (100) is disclosed. The MOS device comprises an n-well region (113) with a top layer (108) of opposite conductivity. A thin layer of oxide (124) is formed over the top layer (108).

### FIELD OF THE INVENTION

The present invention relates to high voltage MOS devices and more specifically to a high voltage MOS device with no field oxide layer overlying the p-region.

### BACKGROUND OF THE INVENTION

When designing high voltage metal oxide (MOS) devices two criteria must be kept in mind. First, the device should have a very high breakdown voltage (V_{BD})Second, the device, when operating, should have as low an on-resistance (RDS_{ON}) as possible. One problem is that techniques and structures that tend to maximize V_{BD} tend to adversely affect RDS_{ON} and vice versa.

To overcome this problem, different designs have been proposed to form devices with acceptable combinations of V_{BD} and RDS_{ON}. One such family of devices is fabricated according to the reduced surface field (RESURF) principle. These devices utilize an extended drain region (in one embodiment a n-well) to support high off-state voltage (V_{BD}). These devices have a maximum net number of charges in the drain area of about 1×10² cm⁻² before avalanche breakdown occurs. This maximum charge sets up the lowest RDS_{ON} possible since RDS_{ON} is proportional to the charge in the drain region.

To help alleviate this problem, some devices utilize a top layer of a conductivity type opposite the extended drain region (in one embodiment a p-type layer) inside the drain region. The top layer allows for a drain region having approximately double the charge than previous designs, which decreases the RDS_{ON}. The top layer helps to deplete the extended drain when the extended drain is supporting high voltage, thus allowing for high breakdown voltage.

Typically, a thick layer of field oxide is formed along the drift region overlying the entire top layer region. This is to protect the device from mobile impurities. However, the field oxide layer tends to consume the top layer. Because it is difficult to predict how much of the top layer will be consumed by the field oxide layer it makes the formation of the top layer in the drain region uncontrollable and unpredictable. As the top layer is consumed, it is unable to deplete the drain region as effectively and decreases V_{BD}. Also, by consuming the top layer the drain region can not support as high a charge and RDS_{ON} is increased.

One solution suggested is to increase the thickness of the top layer thus leaving more top layer remaining after partial consumption by the field oxide layer. However, the top portion of the drain region has the highest concentration of dopants and therefore gives the lowest RDS_{ON}. By increasing the thickness of the top region, less of the high concentration drain region is available. This increases RDS_{ON}. What is needed is a device and method, which eliminates the need for the field oxide layer over the top layer.

### BRIEF DESCRIPTION OF THE DRAWINGS

For a more complete understanding of the present invention and advantages thereof, reference is now made to the following descriptions, taken in conjunction with the following drawings, in which like reference numerals represent like parts, and in which:

FIG. 1 is a cross-sectional side view of a half-cell of the device;

FIG. 2 is a cross-sectional side view of a half cell of the device with an enhanced n-well;

FIG. 3 is a cross-sectional side view of a half cell of the device with multiple p-top layers in the n-well;

FIGS. 4a, 4b and 4c are cross-sectional top views of the device with different arrangements of the p-top layers; and

FIGS. 5-7 illustrate a method for manufacturing the device.

### DETAILED DESCRIPTION OF THE DRAWINGS

The present invention relates to high voltage MOS devices that have a high breakdown voltage and low on-resistance. While the following discussions are described below using n-channel devices, the discussion also pertains to p-channel devices, which may be formed by reversing the conductivity of the described regions and layers. The device overcomes disadvantages discussed previously by eliminating the thick oxide layer that is typically formed over the p-top layers. By eliminating the thick oxide layer, the formation of the p-top layer can be controlled better, which will decrease breakdown voltage and increase RDS_{ON}.

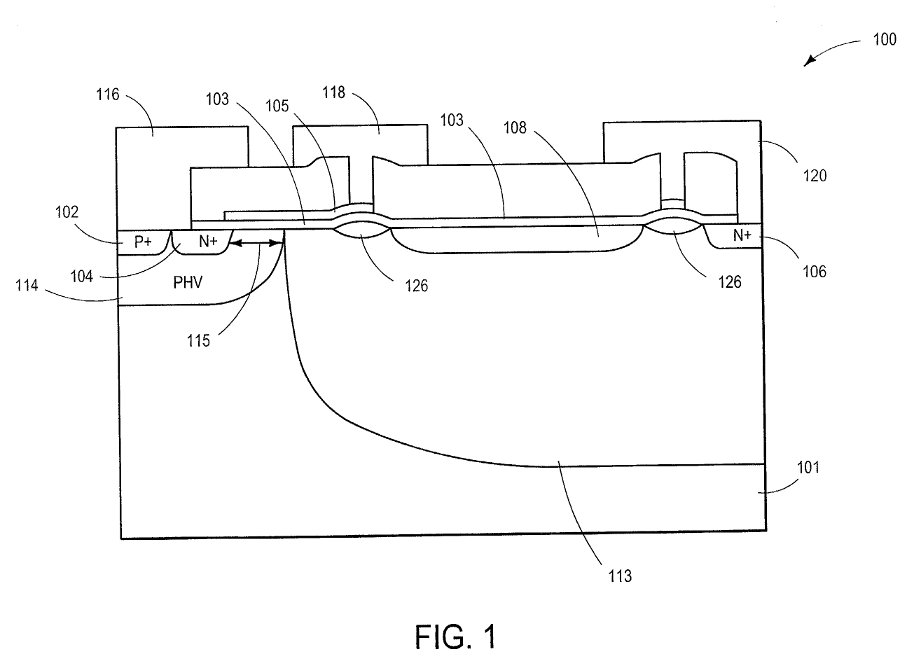

FIG. 1 is a cross-sectional side view of an exemplary n-channel MOS device 100. Illustrated is a lightly doped p-type substrate region 101. A N+ source diffusion region 104 is formed at the top of substrate region 101. A P+ diffusion region 102 is formed adjacent to N+ source diffusion region 104. The P+ diffusion region 102 increases the integrity of the source to substrate connection as well as reduces the device's susceptibility to parasitic bipolar effects. Associated with N+ source diffusion region 104 and P+ region 102 is a source electrode 116, which provides electrical contact to the N+ source region 104 and the P+ region 102.

An insulating layer 103 (comprising silicon dioxide or some other insulating dielectric material) is formed over the top of the substrate 101. Over the insulating layer 103 is a gate 105, typically comprising silicon. A gate contact 118 is coupled to the gate 105.

A drain diffusion region 106 is formed at the top of substrate 101 away from source region 104 and connected electrically to drain contact 120. Drain contact 120 may comprise a number of conductive metals or metal alloys. An optional diffused P region 114 may be formed in the substrate 101 to enclose P+ region 102 and N+ source region 104. The diffused P region 114 is a high voltage P-region (PHV) and helps to reduce the device's susceptibility to drain-to-source punch through as well as helps to provide an appropriate threshold voltage. A channel region 115 exists from the source region 104 to the end of the diffused p-region 114.

A n-well region 113 is formed in substrate 101 such that the n-well region extends from the surface of the substrate adjacent to the channel region 115 into the substrate and encloses the drain region 106. N-well 113 is formed via implanting dopants. In n-well 113, in one embodiment, the net number of charges can approach 2×10¹² cm⁻². A p-top layer 108 is formed within n-well 113 for charge balancing. P-top layer 108 is typically located adjacent to the top of n-well 113. The p-top layer 108 allows for downward depletion when voltage is blocked. This, along with the upward depletion from the bottom of n-well 113, allows for a high breakdown voltage. The increased doping in the n-well 113 allows for lower on-resistance. While a n-well region 113 is shown, the region may also be a n-epi layer formed by epitaxial growth.

As discussed in the background, in prior art devices, a relatively thick layer of field oxide (approximately 1 micron thick) is typically formed over the drift region including over the p-top layer 108. This is done to protect the device from mobile impurities that could penetrate device 100 and degrade device performance. However, in the present invention the p-top layer 108 in the n-well 113 protects the device from mobile impurities. Since a thick oxide layer is not needed over p-top layer 108, the insulating layer 103 may be extended over the p-top layer 108. This layer, in one embodiment, is less than 1000 angstroms thick. The insulation layer 103 is formed before the formation of the p-top layer 108 and the p-top layer can be implanted through the insulation layer 103. This results in several advantages over the prior art. First, thick oxide layers react with and consume the p-top layer, reducing its concentration. This can adversely affect both breakdown voltage and on-resistance as well as making the controllability and predictability of p-top layer 108 nearly impossible. By eliminating the thick field oxide layer, a better, more predictable p-top layer 108 can be formed. The p-top layer 108 allows for downward depletion when blocking voltage leading to a higher breakdown voltage. Additionally, the p-top layer 108 can be made as a shallow p-top layer 108 since there is no fear of consumption by a field oxide layer. This results in higher concentration of dopants in the n-well 113, which in turn results in lower RDS_{ON}.

Device 100 has thick field oxide islands 126 under the gate contact 118 and optionally by the drain contact 120 near either end of the p-top layer 108. By providing a metal layer (such as a contact) over an oxide layer the electric field is redistributed in that area. This is known as the field plate effect.

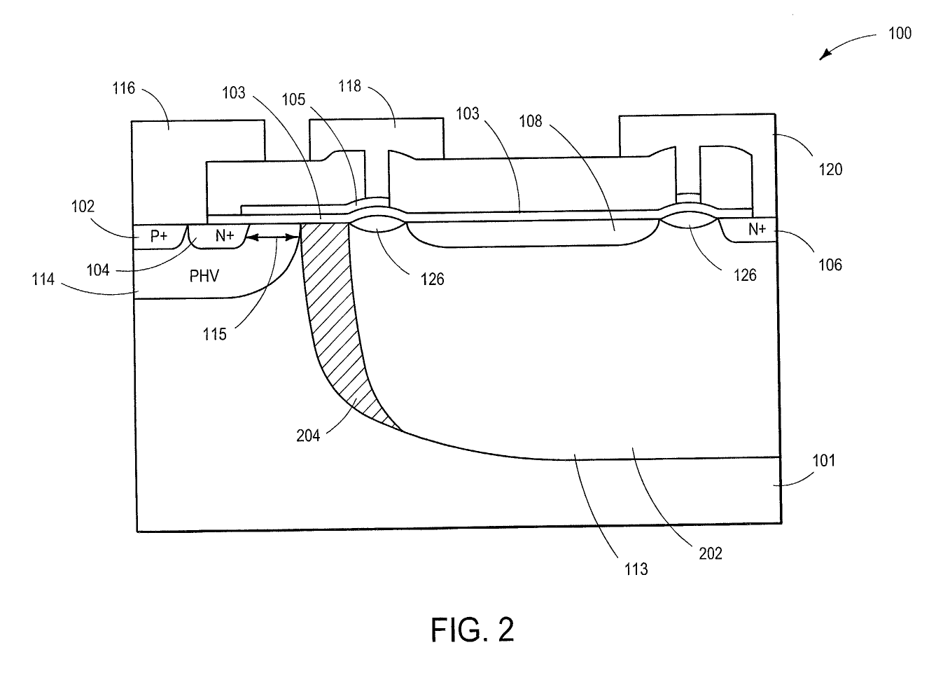

FIG. 2 is a cross sectional side view of a half cell of the device with an enhanced n-well. In this embodiment, n-well 113 comprises a first region 202 of high dopant concentration offset from a second region 204 of lower dopant concentration. The regions are formed by performing two separate n-well implants. The first implant is a relatively low concentration implant. Then, a second implant of higher concentration is performed. The second implant is laterally offset from the first implant by a certain amount. This forms the two separate regions. This embodiment allows for a lower concentration of dopants, under the gate region next to the channel region 115, which increases the depletion region extension into the n-well 113, which helps prevent premature breakdowns that occur at critical fields at the surface of the device.

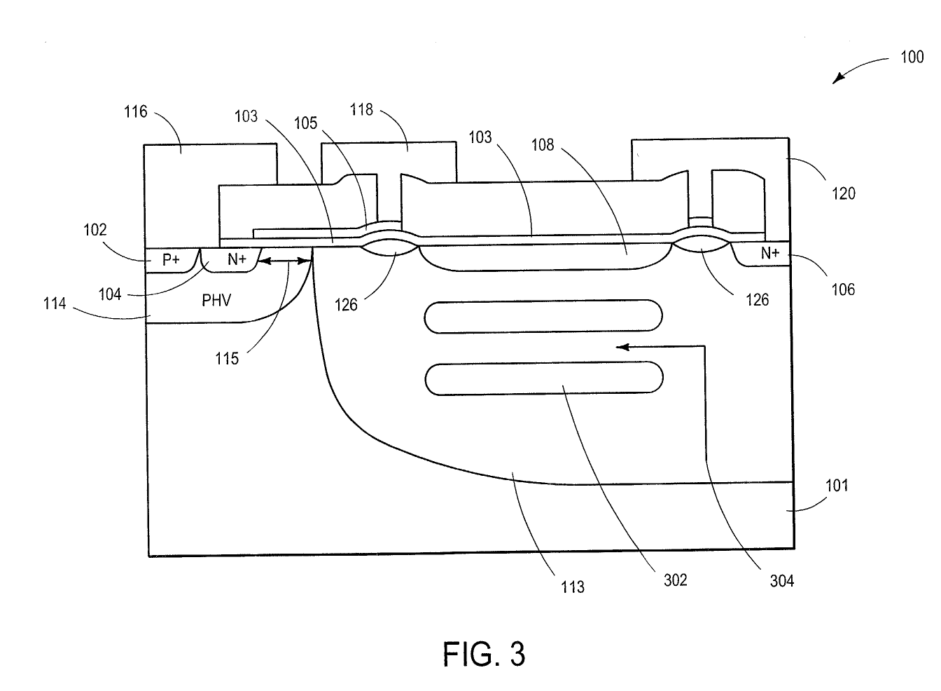

FIG. 3 is a cross-sectional side view of a half cell of the device with multiple p-regions in the n-well. As seen in FIG. 3, additional p-regions 302 are formed within n-well 113 and below p-top layer 108. These p-regions are formed, for example, by high-energy ion implantation. This results in a n-well 113 with multiple p-regions 302 separated by conductivity channels 304. The conductivity channels allow for a lower on resistance by allowing for a large charge to be supported in each conductivity channel.

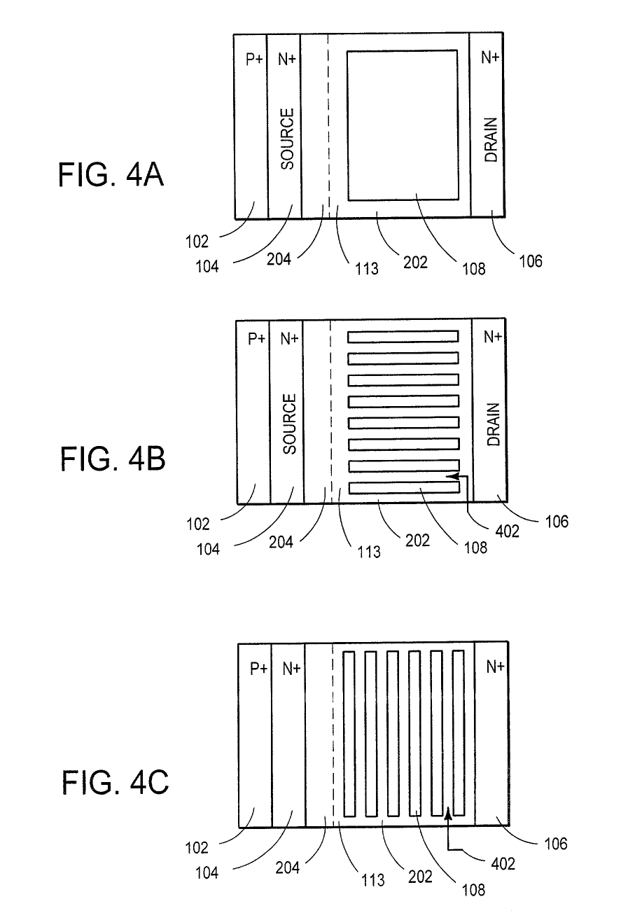

FIG. 4a is a cross-sectional top view of device 100. Illustrated is the source region 104, the adjacent p-r0egion 102, a drain region 106 and p-top layer 108 which, in this embodiment, is one solid p-top layer. P-top layer 108 overlies n-well 113, which, in this illustration comprises the first region 202 of high dopant concentration and the second region 204 of low dopant concentration. Of course, in this invention, p-top layer 108 can be formed in a conventional n-well 113 as well. As discussed in conjunction with FIG. 3, there can be multiple p-regions under the p-top layer 108. P-top layer 108 also is not necessary at the top but can be below the surface of the n-well 113.

FIG. 4b illustrates device 100 with p-top layer 108 comprising multiple “stripes” of p-top material each one separated by a channel region 402 which is parallel to current flow (current will flow from the source to the drain). FIG. 4b also illustrates n-well 113 having a first region of high dopant concentration 202 and a second region of lower dopant concentration 204. FIG. 4c is similar to FIG. 4b except the “stripes” of p-top layer 108 are aligned perpendicular to current flow. Again, n-well 113 is illustrated having a first region of high dopant concentration 202 and a second region of low dopant concentration 204 although a conventional n-well 113 can be used. While FIGS. 4b and 4c show “striped” regions, other shapes and patterns can be interchanged. Examples include a plurality of square, circular and polygonal areas of p-top layer 108.

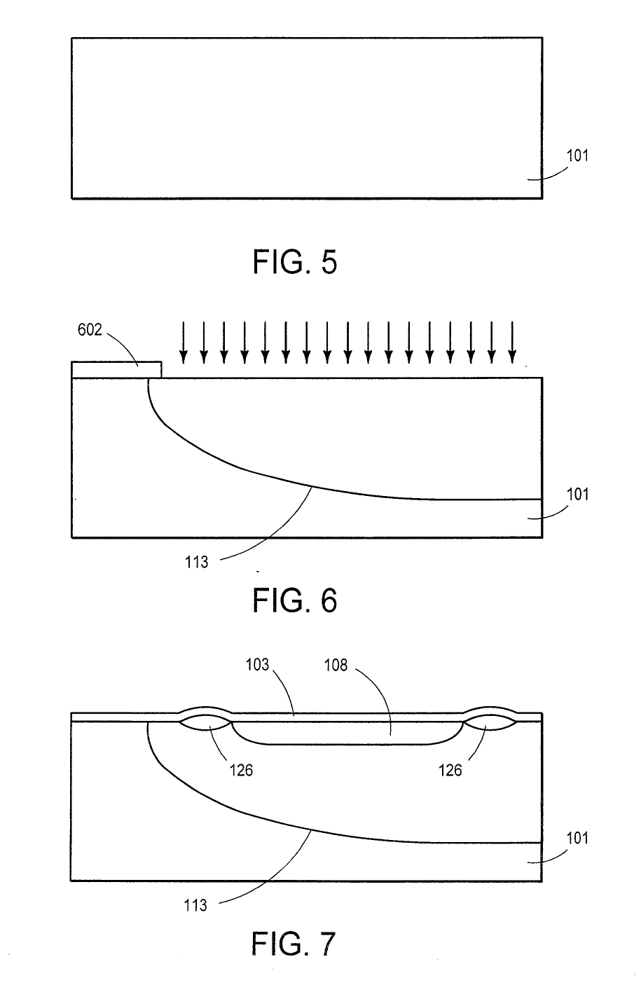

FIGS. 5 through 7 illustrate steps in an exemplary process to manufacture the device. In a first step, illustrated in FIG. 5, a p substrate 101 is provided. In a second step, illustrated in FIG. 6, an n-well implant is performed. In this step dopants are implanted through an opening in a first mask 602. A thermal cycle is performed to diffuse the n-well 113. Next, a layer of dielectric, typically oxide or gate oxide is applied over the top of the substrate. Then, in a fourth step, a p-top implant is performed through a mask opening. A heating cycle is then performed to diffuse the p-top layer 108. Also, islands of field oxide 126 are formed adjacent to, but not over the p-top layer 108. These steps are illustrated in FIG. 7. In an alternative embodiment, islands of field oxide layer 126 may be formed before the p-top implant and the p-top implant will be self-aligned to the islands of field oxide.

In step five, an optional PHV implant and drive is performed. Then, the p-region in the PHV region is formed along with the n-type source and n-drain regions. After that a source/drain anneal is completed and any other necessary steps are performed. The final device is illustrated in FIG. 1.

Thus, it is apparent that there has been provided an improved semiconductor device. It should be understood that various changes, substitutions, and alterations can be made herein without departing from the spirit and scope of the present invention as defined by the following claims.

What is claimed:

1. A semiconductor device comprising:
a substrate of a first conductivity type;
a first region of a second conductivity type formed in a substrate as an extended drift region;
a second region of the first conductivity formed within the first region to provide charge balancing in the first region; and
a thin layer of dielectric formed over the second region.

2. The semiconductor device of claim 1, wherein a thick layer of field oxide is formed under a gate contact and near one end of the second region.

3. The semiconductor device of claim 1, wherein a thick layer of field oxide is formed under a drain contact and near one end of the second region.

4. The device of claim 1, wherein the first region is an epitaxial layer.

5. The device of claim 1, wherein the first region is a well region.

6. The device of claim 5, wherein the well region comprises a first area of high dopant concentration and a second area of low dopant concentration.

7. The device of claim 1, wherein a diffused region of the first conductivity type surrounds a source region.

8. A method of manufacturing a semiconductor device comprising:
forming a first region of a first conductivity type within a substrate to provide an extended drift region;
forming a thin layer of dielectric over the region of a first conductivity; and
forming a second region of a second conductivity type in the first region to balance charges in the first region.

9. The method of claim 8, wherein the step of forming a first region comprises forming an epitaxial layer in the substrate.

10. The method of claim 8, wherein the step of forming a first region comprises performing a first implant of low concentration and performing a second implant of a higher concentration, wherein the second implant is laterally offset from the first implant.

11. The method of claim 8, further comprising the step of forming a diffused region of a second conductivity type to surround a source region.

12. The method of claim 8, further comprising forming an island of thick field oxide under a gate contact and near one end of the second region.

13. The method of claim 8, further comprising forming an island of thick field oxide under a drain contact and near one end of the second region.

14. The method of claim 8, wherein the step of forming a first region comprises forming a well region of a first conductivity type.

15. A high voltage DMOS device comprising:
a first region of a first conductivity type formed in a substrate;
a second region of a second conductivity formed within the first region of a first conductivity type;
a thin layer of oxide formed over the surface of the substrate including the second region of a second conductivity type;
a drain region formed within the first region of the first conductivity type;
a high voltage region of the second conductivity type formed within the substrate adjacent to the first region, the high voltage region being lightly doped; and,
a source region formed within the high voltage region.

16. The device of claim 15, wherein the first region of a first conductivity type is an epitaxial region.

17. The device of claim 15, wherein the first region of a first conductivity type is a well region formed in the substrate.

18. The device of claim 17, wherein the well region has a first area of high dopant concentration and a second area of low dopant concentration.

19. The device of claim 15, further comprising a field oxide layer underlying a gate contact.

20. The device of claim 19 further comprising a field oxide layer underlying a drain contact.

21. A semiconductor device comprising:
a substrate;
a first region formed in a substrate by implanting dopants of a first conductivity type into the substrate to form an extended drain region;
a second region formed by implanting dopants of a second conductivity type into the first region to balance charges in the first region; and
a thin layer of dielectric material formed over the first region.

22. The device of claim 21, wherein a thick region of field oxide is formed under a gate contact.

23. The device of claim 21, wherein a thick layer of field oxide is formed under a drain region.

24. The device of claim 21, wherein the first region is an epitaxial region.

25. The device of claim 21, wherein the first region is a well region.

26. The device of claim 25, wherein the well region comprises a high dopant area and a low dopant area.

27. The device of claim 26, wherein the low dopant area is adjacent to a channel region.

28. The device of claim 21, further comprising one or more vertical layers of a second conductivity type formed underneath the second region.
